(19) United States
(12) Patent Application Publication
(10) Pub. No.: US 2026/0082884 A1
(43) Pub. Date: Mar. 19, 2026

(54) SEMICONDUCTOR PACKAGE

(71) Applicant: SAMSUNG ELECTRONICS CO., LTD., Suwon-si (KR)

(72) Inventors: Sunghyun Sim, Suwon-si (KR); Juhyeon Kim, Suwon-si (KR); Jaejun Lee, Suwon-si (KR)

(21) Appl. No.: 19/323,691

(22) Filed: Sep. 9, 2025

(30) Foreign Application Priority Data
Sep. 19, 2024 (KR) 10-2024-0126378

(51) Int. Cl. H10W 20/20; H10W 72/20; H10W 72/90; H10W 74/15; H10W 90/00

(52) U.S. Cl. CPC H10W 20/20; H10W 72/234; H10W 72/923; H10W 72/934; H10W 72/9415; H10W 72/942; H10W 74/15; H10W 90/722; H10W 90/732

(57) ABSTRACT

A semiconductor package includes a substrate having first and second surfaces opposite to each other in a vertical direction, a through electrode extending through the substrate and having an upper surface that is convex or concave, a protective pattern structure on the second surface of the substrate, and a conductive pad extending through the protective pattern structure. An upper portion of the conductive pad contacts an upper surface of the protective pattern structure. A lower portion of the conductive pad contacts an upper surface of the through electrode.

### CROSS-REFERENCE TO RELATED APPLICATION

This application claims priority under 35 U.S.C. § 119 to Korean Patent Application No. 10-2024-0126378, filed on Sep. 19, 2024 in the Korean Intellectual Property Office (KIPO), the entirety of which is incorporated by reference herein.

### BACKGROUND

In a method of manufacturing a semiconductor package including through silicon via (TSV), a wafer is flipped, a rear portion of the wafer is grinded to expose an upper surface of the TSV, a passivation layer is formed on a backside surface of the wafer to cover the TSV, a CMP process is performed on the passivation layer until an upper surface of the TSV is exposed, and a conductive pad is formed to contact the exposed upper surface of the TSV.

### SUMMARY

Some aspects of this disclosure describe semiconductor devices having a conductive pad that contacts an upper surface of a TSV well, and methods of forming the same.

Some aspects of this disclosure describe semiconductor packages having enhanced electrical characteristics.

According to some implementations of the present disclosure, there is provided a semiconductor package. The semiconductor package may include a substrate having first and second surfaces opposite to each other in a vertical direction, a through electrode extending through the substrate and having an upper surface that is convex or concave, a protective pattern structure on the second surface of the substrate, and a conductive pad extending through the protective pattern structure. An upper portion of the conductive pad may contact an upper surface of the protective pattern structure. A lower portion of the conductive pad may contact an upper surface of the through electrode.

According to some implementations of the present disclosure, there is provided a semiconductor package. The semiconductor package may include a substrate having first and second surfaces opposite to each other in a vertical direction, a through electrode extending through the substrate, a protective pattern structure on the second surface of the substrate, and a conductive pad. The conductive pad may include a seed pattern on an upper surface and a sidewall of the protective pattern structure and an upper surface of the through electrode, and a first conductive pattern on the seed pattern. A portion of the first conductive pattern may overlap the sidewall of the protective pattern structure in a horizontal direction, and a portion of the first conductive pattern may overlap the upper surface of the protective pattern structure in a vertical direction. Each of a lower surface and an upper surface of the conductive pad may be at least partially curved.

According to some implementations of the present disclosure, there is provided a semiconductor package. The semiconductor package may include a first semiconductor chip, a conductive bump and a second semiconductor chip. The first semiconductor chip may include a first substrate having first and second surfaces opposite to each other in a vertical direction, a first through electrode extending through the first substrate and having an upper surface that is convex or concave, a first protective pattern structure on the second surface of the first substrate, and a first conductive pad extending through the first protective pattern structure. The conductive bump may be disposed on the first conductive pad. The second semiconductor chip may include a second substrate having first and second surfaces opposite to each other in the vertical direction, a second through electrode extending through the second substrate, and a second conductive pad on the first surface of the second substrate and contacting an upper surface of the conductive bump. An upper portion of the first conductive pad may contact an upper surface of the first protective pattern structure. A lower portion of the first conductive pad may contact an upper surface of the through electrode.

According to some implementations, in a method of manufacturing a semiconductor package, in order to form a conductive pad contacting a through electrode that extends through a substrate, a photo process using an independent photo alignment key may not be performed, so that the number of processes for manufacturing the semiconductor package may be reduced.

### BRIEF DESCRIPTION OF THE DRAWINGS

FIG. 1 is a cross-sectional view illustrating a an example of a semiconductor package.

FIG. 2 is an enlarged cross-sectional view of region X of FIG. 1.

FIG. 3 is an enlarged cross-sectional view of region Y of FIG. 1.

FIGS. 4 to 18 are cross-sectional views illustrating an example of a method of manufacturing a semiconductor package.

FIG. 19 is a cross-sectional view illustrating an example of a semiconductor package.

FIG. 20 is a cross-sectional view illustrating an example of a semiconductor package.

FIG. 21 is a cross-sectional view illustrating an example of a semiconductor package.

FIG. 22 is a cross-sectional view illustrating an example of an electronic device.

### DETAILED DESCRIPTION

In the subsequent description, it will be understood that, although the terms “first,” “second,” and/or “third” may be used herein to describe various materials, layers, regions, pads, electrodes, patterns, structure and/or processes, these terms are only used as labels to distinguish one material, layer, region, pad, electrode, pattern, structure or process from another material, layer, region, pad, electrode, pattern, structure or process, without suggesting any particular order or arrangement. Thus, “first”, “second” and/or “third” may be used selectively or interchangeably for each material, layer, region, electrode, pad, pattern, structure or process respectively.

Hereinafter, a direction substantially parallel to an upper surface of a wafer or a substrate may be referred to as a horizontal direction, and a direction substantially perpendicular to the upper surface of the wafer or the substrate may be referred to as a vertical direction.

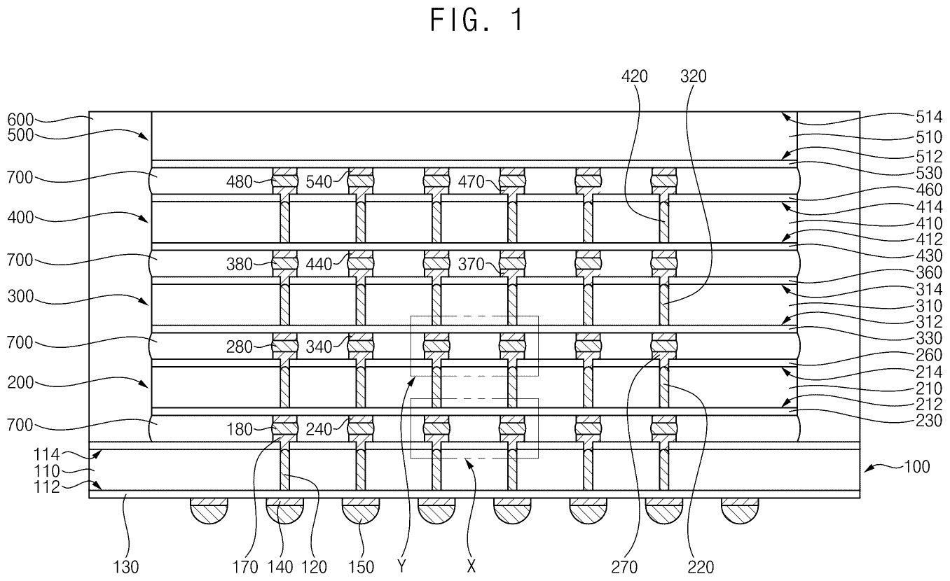

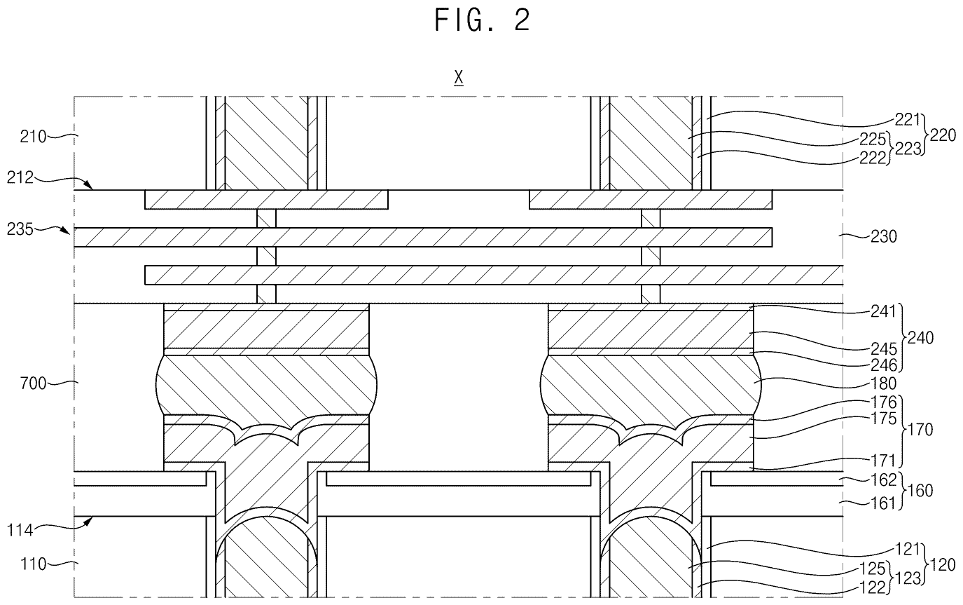

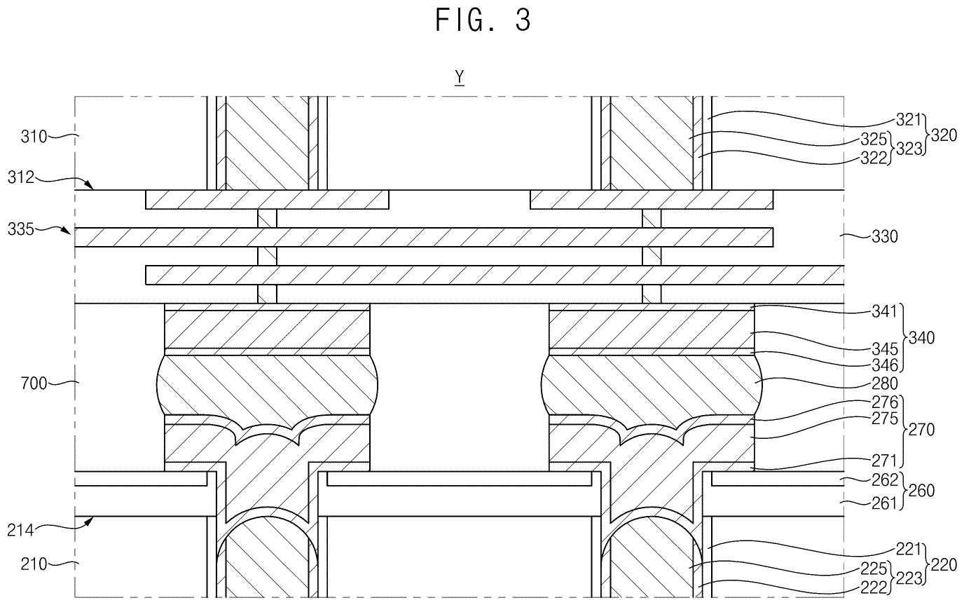

FIG. 1 is a cross-sectional view illustrating an example of a semiconductor package. FIG. 2 is an enlarged cross-sectional view of region X of FIG. 1. FIG. 3 is an enlarged cross-sectional view of region Y of FIG. 1.

Referring to FIGS. 1 to 3, the semiconductor package may include a first semiconductor chip 100, second to fifth semiconductor chips 200, 300, 400 and 500 sequentially stacked on the first semiconductor chip 100, a bonding layer 700 disposed between the first to fifth semiconductor chips 100, 200, 300, 400 and 500, and a molding member 600 disposed on the first semiconductor chip 100 and covering sidewalls of the second to fifth semiconductor chips 200, 300, 400 and 500.

FIGS. 1 to 3 show that the semiconductor package includes four semiconductor chips 200, 300, 400 and 500 stacked on the first semiconductor chip 100, however, the number of semiconductor chips is not limited thereto, and the semiconductor package may include more than or fewer than four semiconductor chips, e.g., eight or sixteen semiconductor chips. In some implementations, the semiconductor package may be a high bandwidth memory (HBM) package.

In some implementations, the first semiconductor chip 100 may be a buffer die, and may include a logic device, e.g., a controller. Each of the second to fifth semiconductor chips 200, 300, 400 and 500 may be a core die, and may include a volatile memory device, e.g., DRAM device, SRAM device, etc., or a non-volatile memory device, e.g., flash memory device, EEPROM device, etc. Each of the second to fourth semiconductor chips 200, 300 and 400 may also be referred to as a middle core die, and the fifth semiconductor chip 500 may be referred to as a top core die.

The first semiconductor chip 100 may also be referred to as a logic chip or a logic die, and each of the second to fifth semiconductor chips 200, 300, 400 and 500 may also be referred to as a memory chip or a memory die.

The first semiconductor chip 100 may include a first substrate 110 having first and second surfaces 112 and 114 that are opposite to each other in the vertical direction, a first through electrode structure 120 extending through the first substrate 110, a first insulating interlayer and a second insulating interlayer 130 sequentially stacked in the vertical direction on the first surface 112 of the first substrate 110, a first conductive pad 140 on a lower surface of the second insulating interlayer 130, a first conductive connection member 150 on a lower surface of the first conductive pad 140, a first protective pattern structure 160 on the second surface 114 of the first substrate 110, a second conductive pad 170 extending through the first protective pattern structure 160 and contacting an upper surface of the first through electrode structure 120, and a second conductive connection member 180 on the second conductive pad 170.

The first substrate 110 may include a semiconductor material, e.g., silicon, germanium, silicon-germanium, or a III-V group compound semiconductor, e.g., GaP, GaAs, GaSb, etc. In some implementations, the first substrate 110 may be a silicon-on-insulator (SOI) substrate or a germanium-on-insulator (GOI) substrate.

A circuit device, e.g., a logic device may be disposed on the first surface 112 of the first substrate 110. The circuit device may include circuit patterns, which may be covered by the first insulating interlayer.

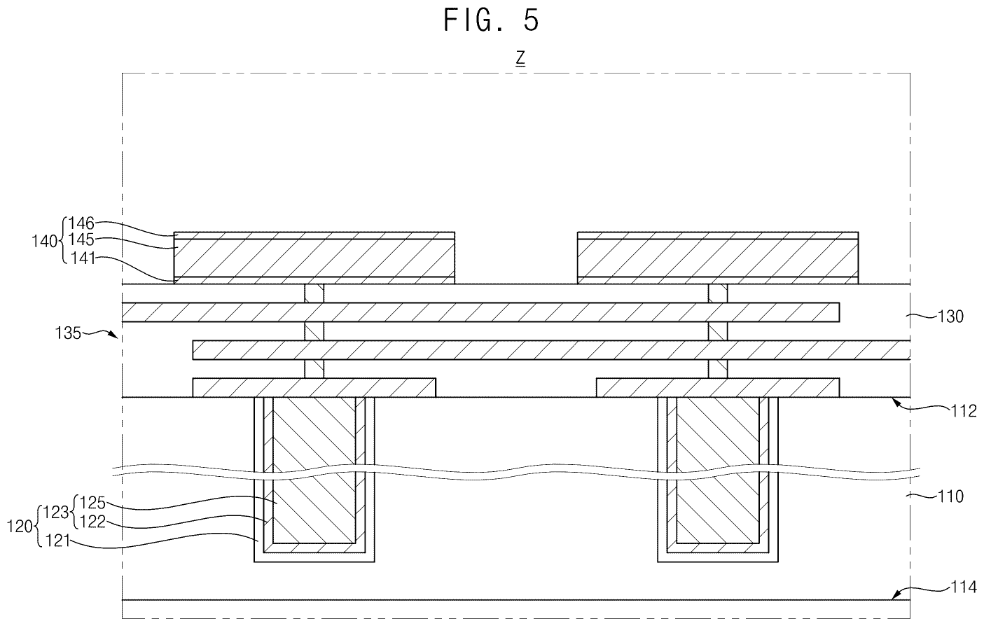

A first wiring structure 135 (see, e.g., FIG. 5) may be disposed in the second insulating interlayer 130. The first wiring structure 135 may include, e.g., wirings, vias, contact plugs, etc.

The first insulating interlayer and the second insulating interlayer 130 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The first conductive pad 140 may be disposed on a lower surface of the second insulating interlayer 130, and may contact the first wiring structure 135 to be electrically connected thereto. In some implementations, a plurality of first conductive pads 140 may be spaced apart from each other in the horizontal direction.

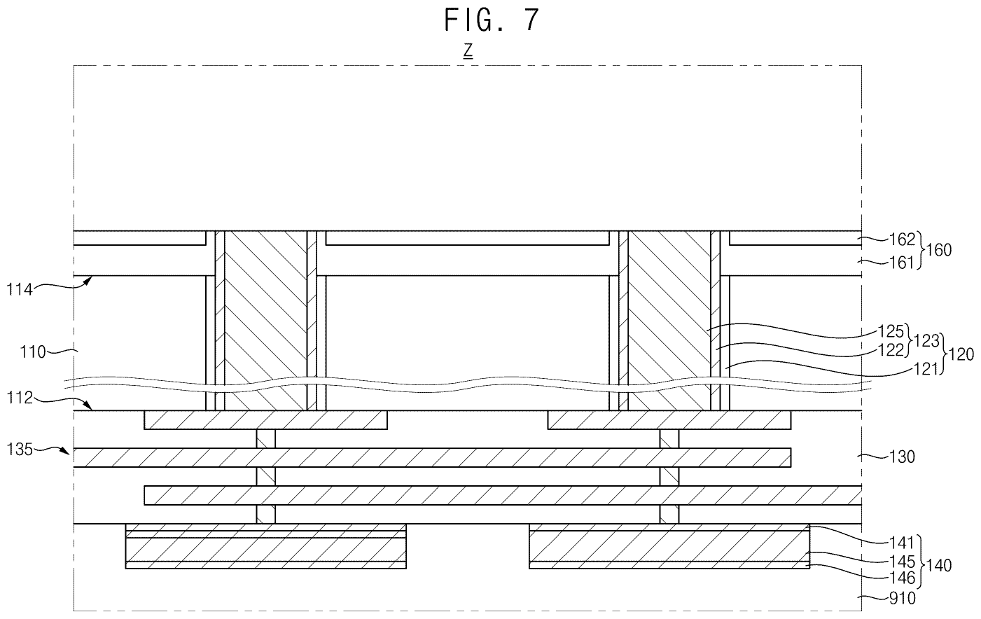

In some implementations, the first conductive pad 140 may include a first seed pattern 141 and first and second conductive patterns 145 and 146 sequentially stacked downwardly in the vertical direction from the lower surface of the second insulating interlayer 130 (refer to FIG. 7). The first seed pattern 141 may include, e.g., titanium and/or copper, and each of the first and second conductive patterns 145 and 146 may include, e.g., nickel and/or copper.

The first conductive connection member 150 may contact the lower surface of the first conductive pad 140. The first conductive connection member 150 may include, e.g., a conductive bump or a conductive ball. The first conductive connection member 150 may include, e.g., a metal such as tin, or a metal alloy such as solder, which is a tin alloy of tin/silver, tin/copper, tin/indium, tin/silver/copper, etc.

The first through electrode structure 120 may extend through the first substrate 110 in the vertical direction. A plurality of first through electrode structures 120 may be spaced apart from each other in the horizontal direction. In some implementations, the first through electrode structure 120 may include a third conductive pattern 125 extending in the vertical direction, a first barrier pattern 122 covering a sidewall of the third conductive pattern 125, and a first insulation pattern 121 covering an outer sidewall of the first barrier pattern 122, and the third conductive pattern 125 and the first barrier pattern 122 may collectively form a first through electrode 123.

In some implementations, the first through electrode 123 may have a curved, e.g., convex upper surface. In some implementations, an uppermost surface of the first through electrode 123 may be substantially coplanar with an upper surface of the first insulation pattern 121 and the second surface 114 of the first substrate 110. However, the arrangement is not limited thereto, and for example, the uppermost surface of the first through electrode 123 may be higher than the upper surface of the first insulation pattern 121 and the second surface 114 of the first substrate 110 and lower than an upper surface of the first protective pattern structure 160.

The third conductive pattern 125 may include a metal, e.g., copper, aluminum, etc., the first barrier pattern 122 may include a metal nitride, e.g., titanium nitride, tantalum nitride, etc., and the first insulation pattern 121 may include an oxide, e.g., silicon oxide, or an insulating nitride, e.g., silicon nitride.

In some implementations, the first through electrode structure 120 may extend through the first substrate 110 and the first insulating interlayer to contact the first wiring structure 135, and may be electrically connected to the first conductive pad 140 through the first wiring structure 135.

As another example, the first through electrode structure 120 may extend through the first substrate 110, the first insulating interlayer and the second insulating interlayer 130 to contact the first conductive pad 140, and may be electrically connected to the first conductive pad 140. As another example, the first through electrode structure 120 may extend through the first substrate 110 to contact one of the circuit patterns included in the circuit device covered by the first insulating interlayer, and may be electrically connected to the first conductive pad 140 through the one of the circuit patterns and the first wiring structure 135.

The first protective pattern structure 160 may contact the second surface 114 of the first substrate 110 and the upper surface of the first insulation pattern 121 included in the first through electrode structure 120. In some implementations, the first protective pattern structure 160 may include a first protective pattern 161 and a second protective pattern 162 stacked in the vertical direction on the first substrate 110 and the first insulation pattern 121.

The first protective pattern 161 may include an oxide, e.g., silicon oxide, and the second protective pattern 162 may include an insulating nitride, e.g., silicon nitride.

The second conductive pad 170 may be electrically connected to the first conductive pad 140 through the first through electrode structure 120 and the first wiring structure 135. In some implementations, a plurality of second conductive pads 170 may be spaced apart from each other in the horizontal direction.

In some implementations, the second conductive pad 170 may include a second seed pattern 171 and fourth and fifth conductive patterns 175 and 176 sequentially stacked on the first through electrode structure 120 and the first protective pattern structure 160.

In some implementations, the second conductive pad 170 may include a lower portion extending through the first protective pattern structure 160 and contacting an upper surface of the first through electrode 123, and an upper portion contacting the lower portion and an upper surface of the first protective pattern structure 160 and having a planar area greater than that of the lower portion. At least a portion of the lower portion of the second conductive pad 170 may overlap the first protective pattern structure 160 in the horizontal direction, and at least a portion of the upper portion of the second conductive pad 170 may overlap the first protective pattern structure 160 in the vertical direction.

In some implementations, a lower surface of the lower portion of the second conductive pad 170 may be curved, for example, concave corresponding to the convex upper surface of the first through electrode 123, which may contact the lower surface of the lower portion of the second conductive pad 170. This configuration is shown, for example, in FIG. 2. The lower portion of the second conductive pad 170 may be interposed between and overlap in the horizontal direction an upper portion of the first through electrode 123 and an upper portion of the first insulation pattern 121. The lower portion of the second conductive pad 170 may also overlap in the horizontal direction a portion of the first substrate 110 adjacent to the second surface 114 of the first substrate 110.

An upper surface of the upper portion of the second conductive pad 170 may include a first central portion that is convex, a second central portion that surrounds the first central portion in a plan view and is concave, and an edge portion that surrounds the second central portion and is substantially flat, corresponding to shapes of the lower surface of the lower portion of the second conductive pad 170 and a portion of the first protective pattern structure 160, which may overlap the upper portion of the second conductive pad 170 in the vertical direction. This configuration is shown, for example, in FIG. 2.

The second seed pattern 171 included in the second conductive pad 170 may include a first portion on the upper surface of the first through electrode 123, a second portion on an upper sidewall of the first insulation pattern 121 and a sidewall of the first protective pattern structure 160, and a third portion on the upper surface of the first protective pattern structure 160.

The second seed pattern 171 may include, e.g., titanium, and the fourth and fifth conductive patterns 175 and 176 may include, e.g., nickel and gold, respectively.

In some implementations, a lower surface of the second conductive connection member 180 may include a first central portion that is concave, a second central portion that surrounds the first central portion in a plan view and is convex, and an edge portion that surrounds the second central portion and is substantially flat, corresponding to a shape of the upper surface of the upper portion of the second conductive pad 170, which may contact the lower surface of the second conductive connection member 180. The second conductive connection member 180 may include, e.g., a conductive bump or a conductive ball including, e.g., a metal such as tin, or solder.

The second semiconductor chip 200 may include a second substrate 210 having first and second surfaces 212 and 214 that are opposite to each other in the vertical direction, a second through electrode structure 220 extending through the second substrate 210, a third insulating interlayer and a fourth insulating interlayer 230 sequentially stacked in the vertical direction on the first surface 212 of the second substrate 210, a third conductive pad 240 on a lower surface of the fourth insulating interlayer 230, a second protective pattern structure 260 on the second surface 214 of the second substrate 210, and a fourth conductive pad 270 extending through the second protective pattern structure 260 and contacting an upper surface of the second through electrode structure 220, and a third conductive connection member 280 on the fourth conductive pad 270.

The second substrate 210 may include a semiconductor material, e.g., silicon, germanium, silicon-germanium, or a III-V group compound semiconductor, e.g., GaP, GaAs, GaSb, etc. In some implementations, the second substrate 210 may be a SOI substrate or a GOI substrate.

A circuit device, e.g., a volatile memory device such as DRAM device, SRAM device, etc., or a non-volatile memory device such as flash memory device, EEPROM device, etc., may be formed on the first surface 212 of the second substrate 210. The circuit device may include circuit patterns, which may be covered by the third insulating interlayer.

A second wiring structure 235 may be disposed in the fourth insulating interlayer 230. The second wiring structure 235 may include, e.g., wirings, vias, contact plugs, etc.

The third insulating interlayer and the fourth insulating interlayer 230 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The third conductive pad 240 may be disposed on the lower surface of the fourth insulating interlayer 230, and may contact the second wiring structure 235 to be electrically connected thereto. The third conductive pad 240 may contact an upper surface of the second conductive connection member 180. In some implementations, a plurality of third conductive pads 240 may be spaced apart from each other in the horizontal direction.

In some implementations, the third conductive pad 240 may include a third seed pattern 241 and sixth and seventh conductive patterns 245 and 246 sequentially stacked on the lower surface of the fourth insulating interlayer 230 downwardly. The third seed pattern 241 may include, e.g., titanium, and the sixth and seventh conductive patterns 245 and 246 may include, e.g., nickel and gold, respectively.

The second through electrode structure 220 may extend through the second substrate 210 in the vertical direction. A plurality of second through electrode structures 220 may be spaced apart from each other in the horizontal direction. In some implementations, the second through electrode structure 220 may include an eighth conductive pattern 225 extending in the vertical direction, a second barrier pattern 222 covering a sidewall of the eighth conductive pattern 225, and a second insulation pattern 221 covering an outer sidewall of the second barrier pattern 222. The eighth conductive pattern 225 and the second barrier pattern 222 may collectively form a second through electrode 223.

In some implementations, the second through electrode 223 may have a convex upper surface. This configuration is shown, for example, in FIG. 3. In some implementations, an uppermost surface of the second through electrode 223 may be substantially coplanar with an upper surface of the second insulation pattern 221 and the second surface 214 of the second substrate 210. However, the arrangement of the uppermost surface of the second through electrode 223 is not limited thereto, and for example, the uppermost surface of the second through electrode 223 may be higher than the upper surface of the second insulation pattern 221 and the second surface 214 of the second substrate 210 and lower than an upper surface of the second protective pattern structure 260.

The eighth conductive pattern 225 may include a metal, e.g., copper, aluminum, etc., the second barrier pattern 222 may include a metal nitride, e.g., titanium nitride, tantalum nitride, etc., and the second insulation pattern 221 may include an oxide, e.g., silicon oxide, or an insulating nitride, e.g., silicon nitride.

In some implementations, the second through electrode structure 220 may extend through the second substrate 210 and the third insulating interlayer to contact the second wiring structure 235, and may be electrically connected to the third conductive pad 240 through the second wiring structure 235.

As another example, the second through electrode structure 220 may extend through the second substrate 210, the third insulating interlayer and the fourth insulating interlayer 230 to contact the third conductive pad 240, and may be electrically connected to the third conductive pad 240. As another example, the second through electrode structure 220 may extend through the second substrate 210 to contact one of the circuit patterns included in the circuit device covered by the third insulating interlayer, and may be electrically connected to the third conductive pad 240 through the one of the circuit patterns and the second wiring structure 235.

The second protective pattern structure 260 may contact the second surface 214 of the second substrate 210 and the upper surface of the second insulation pattern 221 included in the second through electrode structure 220. In some implementations, the second protective pattern structure 260 may include a third protective pattern 261 and a fourth protective pattern 262 stacked in the vertical direction on the second substrate 210 and the second insulation pattern 221.

The third protective pattern 261 may include an oxide, e.g., silicon oxide, and the fourth protective pattern 262 may include an insulating nitride, e.g., silicon nitride.

The fourth conductive pad 270 may be electrically connected to the third conductive pad 240 through the second through electrode structure 220 and the second wiring structure 235. In some implementations, a plurality of fourth conductive pads 270 may be spaced apart from each other in the horizontal direction.

In some implementations, the fourth conductive pad 270 may include a fourth seed pattern 271 and ninth and tenth conductive patterns 275 and 276 sequentially stacked on the second through electrode structure 220 and the second protective pattern structure 260. The fourth seed pattern 271 may include, e.g., titanium, and the ninth and tenth conductive patterns 275 and 276 may include, e.g., nickel and gold, respectively.

The bonding layer 700 may be interposed between the first and second semiconductor chips 100 and 200, and may bond the first and second semiconductor chips 100 and 200 to each other. The bonding layer 700 may surround the second and third conductive pads 170 and 240 and the second conductive connection member 180. The bonding layer 700 may include a non-conductive film such as thermosetting resin.

The third to fifth semiconductor chips 300, 400 and 500 may be sequentially stacked on the second semiconductor chip 200, and the bonding layer 700 may be interposed between the third to fifth semiconductor chips 300, 400 and 500.

Each of the third to fifth semiconductor chips 300, 400 and 500 may have a structure substantially the same as or similar to that of the second semiconductor chip 200, and thus hereinafter, the structures of the third to fifth semiconductor chips 300, 400 and 500 are discussed briefly. The description provided for the second semiconductor chip 200 can apply similarly to the third to fifth semiconductor chips 300, 400 and 500, except where noted otherwise or suggested otherwise by context.

The third semiconductor chip 300 may include a third substrate 310 having first and second surfaces 312 and 314 that are opposite to each other in the vertical direction, a third through electrode structure 320 extending through the third substrate 310, a fifth insulating interlayer and a sixth insulating interlayer 330 sequentially stacked in the vertical direction on the first surface 312 of the third substrate 310, a fifth conductive pad 340 on a lower surface of the sixth insulating interlayer 330, a third protective pattern structure 360 on the second surface 314 of the third substrate 310, and a sixth conductive pad 370 extending through the third protective pattern structure 360 to contact an upper surface of the third through electrode structure 320, and a fourth conductive connection member 380 on the sixth conductive pad 370.

A circuit device, e.g., a memory device may be formed on the first surface 312 of the third substrate 310. The circuit device may include circuit patterns, which may be covered by the fifth insulating interlayer. A third wiring structure 335 may be disposed in the sixth insulating interlayer 330.

The fifth conductive pad 340 may be disposed on the lower surface of the sixth insulating interlayer 330, and may contact the third wiring structure 335 to be electrically connected to the third wiring structure 335. In some implementations, the fifth conductive pad 340 may include a fifth seed pattern 341 and eleventh and twelfth conductive patterns 345 and 346 sequentially stacked on the lower surface of the sixth insulating interlayer 330 downwardly.

The third through electrode structure 320 may extend through the third substrate 310 in the vertical direction. In some implementations, the third through electrode structure 320 may include a thirteenth conductive pattern 325 extending in the vertical direction, a third barrier pattern 322 covering a sidewall of the thirteenth conductive pattern 325, and a third insulation pattern 221 covering an outer sidewall of the third barrier pattern 322. The thirteenth conductive pattern 325 and the third barrier pattern 322 may collectively form a third through electrode 323.

The third protective pattern structure 360 may contact the second surface 314 of the third substrate 310 and the upper surface of the third insulation pattern 321 included in the third through electrode structure 320. In some implementations, the third protective pattern structure 360 may include a fifth protective pattern and a sixth protective pattern stacked in the vertical direction on the third substrate 310 and the third insulation pattern 321.

The sixth conductive pad 370 may be electrically connected to the fifth conductive pad 340 through the third through electrode structure 320 and the third wiring structure 335. In some implementations, the sixth conductive pad 370 may include a sixth seed pattern and fourteenth and fifteenth conductive patterns sequentially stacked on the third through electrode structure 320 and the third protective pattern structure 360.

The bonding layer 700 may be interposed between the second and third semiconductor chips 200 and 300, and may bond the second and third semiconductor chips 200 and 300 to each other. The bonding layer 700 may surround the fourth and fifth conductive pads 270 and 340 and the third conductive connection member 280.

The fourth semiconductor chip 400 may include a fourth substrate 410 having first and second surfaces 412 and 414 that are opposite to each other in the vertical direction, a fourth through electrode structure 420 extending through the fourth substrate 410, a seventh insulating interlayer and an eighth insulating interlayer 430 sequentially stacked in the vertical direction on the first surface 412 of the fourth substrate 410, a seventh conductive pad 440 on a lower surface of the eighth insulating interlayer 430, a fourth protective pattern structure 460 on the second surface 414 of the fourth substrate 410, and an eighth conductive pad 470 extending through the fourth protective pattern structure 460 to contact an upper surface of the fourth through electrode structure 420, and a fifth conductive connection member 480 on the eighth conductive pad 470.

A circuit device, e.g., a memory device may be disposed on the first surface 412 of the fourth substrate 410. The circuit device may include circuit patterns, which may be covered by the seventh insulating interlayer. A fourth wiring structure may be disposed in the eighth insulating interlayer 430.

The seventh conductive pad 440 may be disposed on the lower surface of the eighth insulating interlayer 430, and may contact the fourth wiring structure to be electrically connected to the fourth wiring structure. In some implementations, the seventh conductive pad 440 may include a seventh seed pattern and sixteenth and seventeenth conductive patterns sequentially stacked downwardly in the vertical direction from the eighth insulating interlayer 430.

The fourth through electrode structure 420 may extend through the fourth substrate 410 in the vertical direction. In some implementations, the fourth through electrode structure 420 may include an eighteenth conductive pattern extending in the vertical direction, a fourth barrier pattern covering a sidewall of the eighteenth conductive pattern, and a fourth insulation pattern covering an outer sidewall of the fourth barrier pattern. The eighteenth conductive pattern and the fourth barrier pattern may collectively form a fourth through electrode.

The fourth protective pattern structure 460 may contact the second surface 414 of the fourth substrate 410 and an upper surface of the fourth insulation pattern included in the fourth through electrode structure 420. In some implementations, the fourth protective pattern structure 460 may include a seventh protective pattern and an eighth protective pattern stacked in the vertical direction on the fourth substrate 410 and the fourth insulation pattern.

The eighth conductive pad 470 may be electrically connected to the seventh conductive pad 440 by the fourth through electrode structure 420 and the fourth wiring structure. In some implementations, the eighth conductive pad 470 may include an eighth seed pattern and nineteenth and twentieth conductive patterns sequentially stacked upwardly in the vertical direction from the fourth through electrode structure 320 and the fourth protective pattern structure 460.

The bonding layer 700 may be interposed between the third and fourth semiconductor chips 300 and 400 and may bond the third and fourth semiconductor chips 300 and 400 to each other. The bonding layer 700 may surround the sixth and seventh conductive pads 370 and 440 and the fourth conductive connection member 380.

The fifth semiconductor chip 500 may include a fifth substrate 510 having first and second surfaces 512 and 514 that are opposite to each other in the vertical direction, a ninth insulating interlayer and a tenth insulating interlayer 530 sequentially stacked in the vertical direction on the first surface 512 of the fifth substrate 510, and a ninth conductive pad 540 on a lower surface of the tenth insulating interlayer 530.

A circuit device, e.g., a memory device may be disposed on the first surface 512 of the fifth substrate 510. The circuit device may include circuit patterns, which may be covered by the ninth insulating interlayer. A fifth wiring structure may be disposed in the tenth insulating interlayer 530.

The ninth conductive pad 540 may be disposed on the lower surface of the tenth insulating interlayer 530, and may contact the fifth wiring structure to be electrically connected to the fifth wiring structure. In some implementations, the ninth conductive pad 540 may include a ninth seed pattern and twenty-first and twenty-second conductive patterns sequentially stacked downwardly in the vertical direction from the tenth insulating interlayer 530.

The bonding layer 700 may be interposed between the fourth and fifth semiconductor chips 400 and 500 and may bond the third and fourth semiconductor chips 400 and 500 to each other. The bonding layer 700 may surround the eighth and ninth conductive pads 470 and 540 and the fifth conductive connection member 480.

The first to fifth semiconductor chips 100, 200, 300, 400 and 500 may be electrically connected to each other by the first to fourth through electrodes (or through electrode structures) 120, 220, 320 and 420 extending through the first to fourth substrates 110, 210, 310 and 410, respectively, the first to third wiring structures 135, 235 and 335 and the fourth and fifth wiring structures electrically connected thereto, the first to ninth conductive pads 140, 170, 240, 270, 340, 370, 440, 470 and 540 electrically connected thereto, and the second to fifth conductive connection members 180, 280, 380 and 480 electrically connected thereto, and electrical signals, e.g., data signals, control signals, etc., may be transferred to each other.

The first conductive connection member 150 may contact the first conductive pad 140, and electrical signals may be transferred from the first conductive pad 140 to an external device.

The molding member 600 may cover sidewalls of the second to fifth semiconductor chips 200, 300, 400 and 500 and sidewalls of the bonding layers 700 on the first semiconductor chip 100, and an upper surface of the molding member 600 may be substantially coplanar with an upper surface of the fifth semiconductor chip 500. The molding member 600 may include a polymer, e.g., epoxy molding compound (EMC).

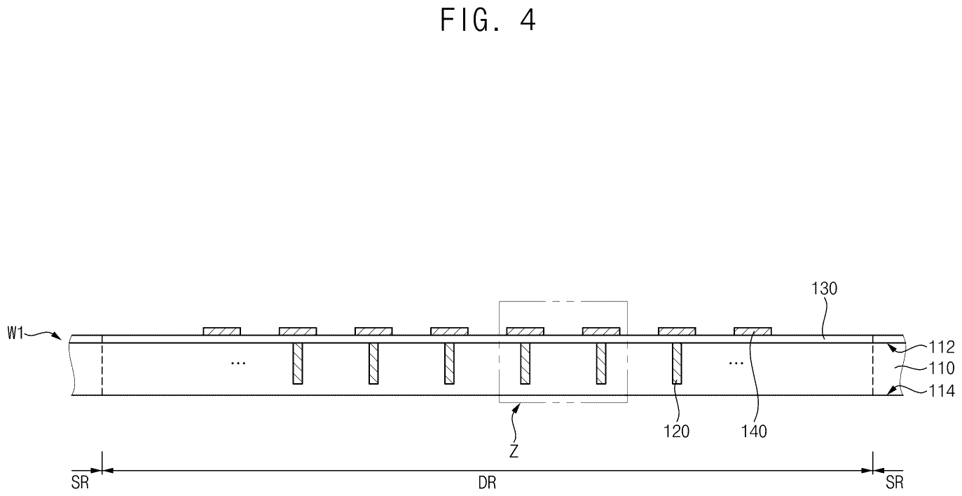

As illustrated below with reference to FIGS. 4 to 18, in some implementations, when the semiconductor package is manufactured, e.g., instead of forming a photo alignment key for each of the second, fourth, sixth and eighth conductive pads 170, 270, 370 and 470, upper portions of the first to fourth through electrode structures 120, 220, 320 and 420 may be removed to form height differences from the first to fourth protective pattern structures 160, 260, 360 and 460, so that each of the second, fourth, sixth and eighth conductive pads 170, 270, 370 and 470 may be formed using (e.g., based on) the height differences, e.g., using the height differences as a photo alignment key. However, in some implementations, photo alignment keys are also formed, and their incorporation should not be understood as being outside the scope of this disclosure.

Thus, the second, fourth, sixth and eighth conductive pads 170, 270, 370 and 470 that may be formed on the first to fourth through electrode structures 120, 220, 320 and 420, respectively, may include lower portions extending through the first to fourth through electrode structures 120, 220, 320 and 420, which may have shapes corresponding to the shapes of the upper surfaces of the first to fourth through electrode structures 120, 220, 320 and 420, respectively.

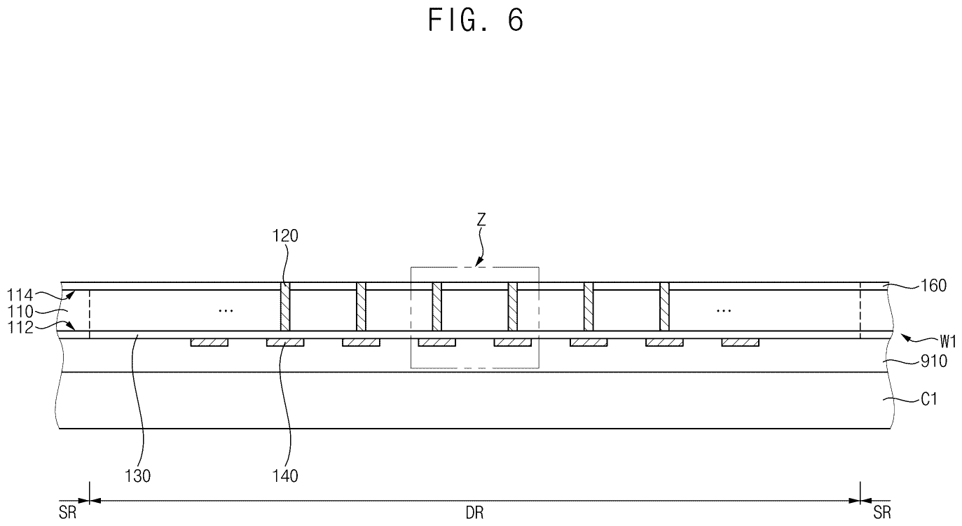

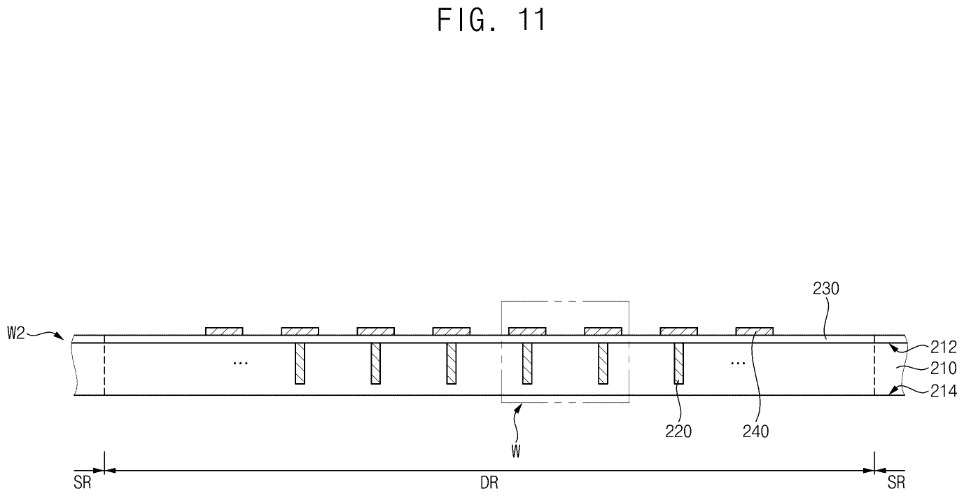

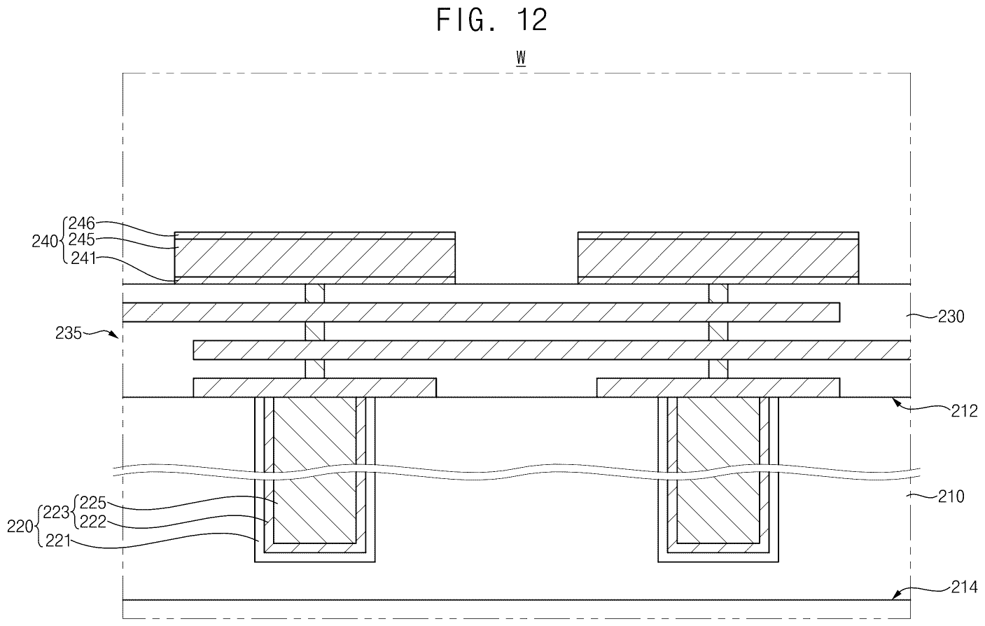

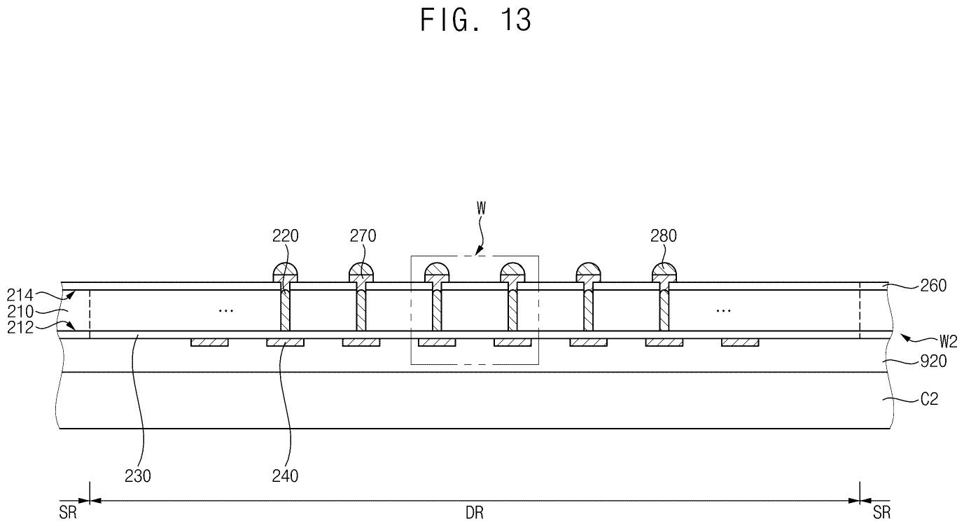

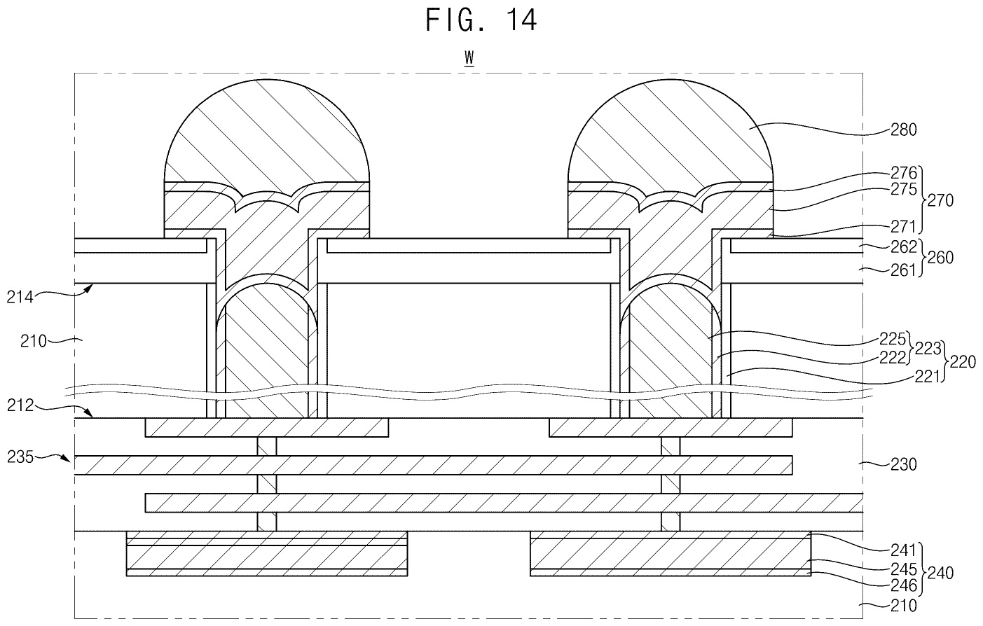

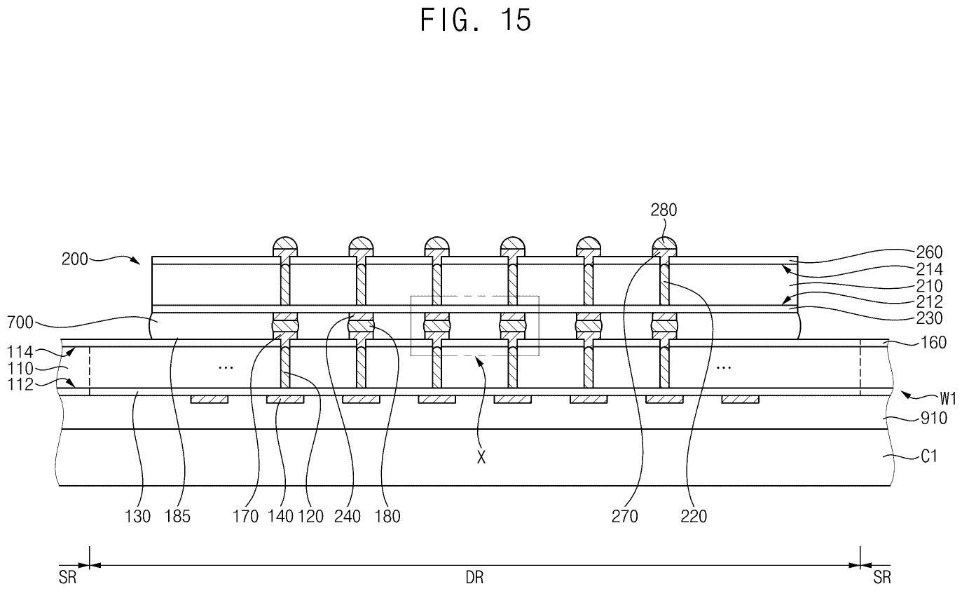

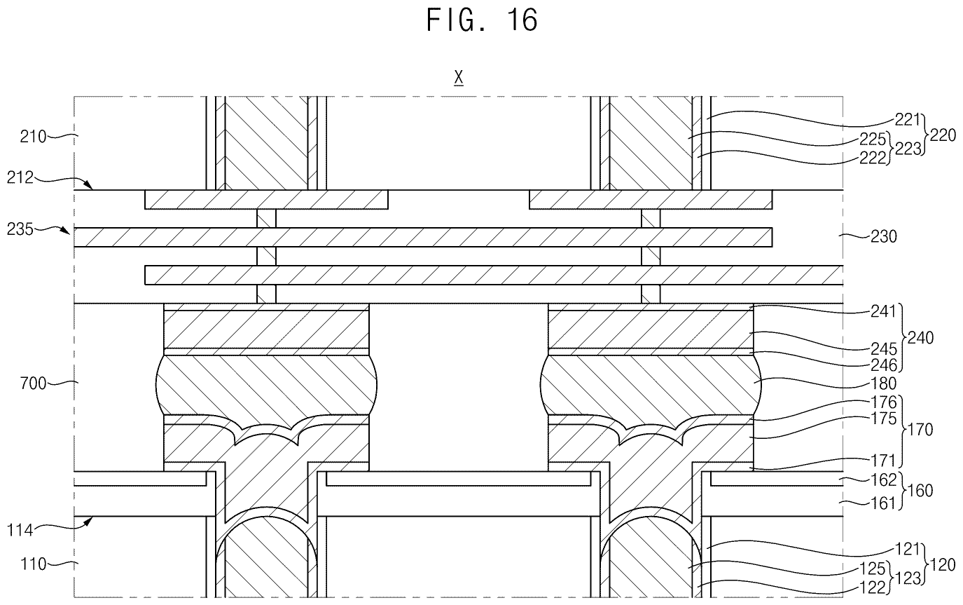

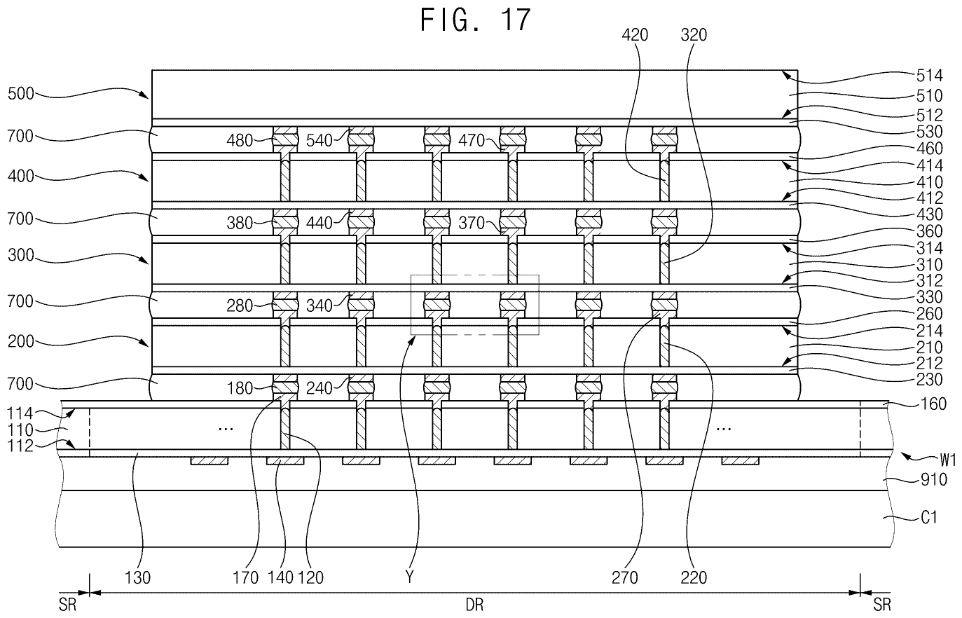

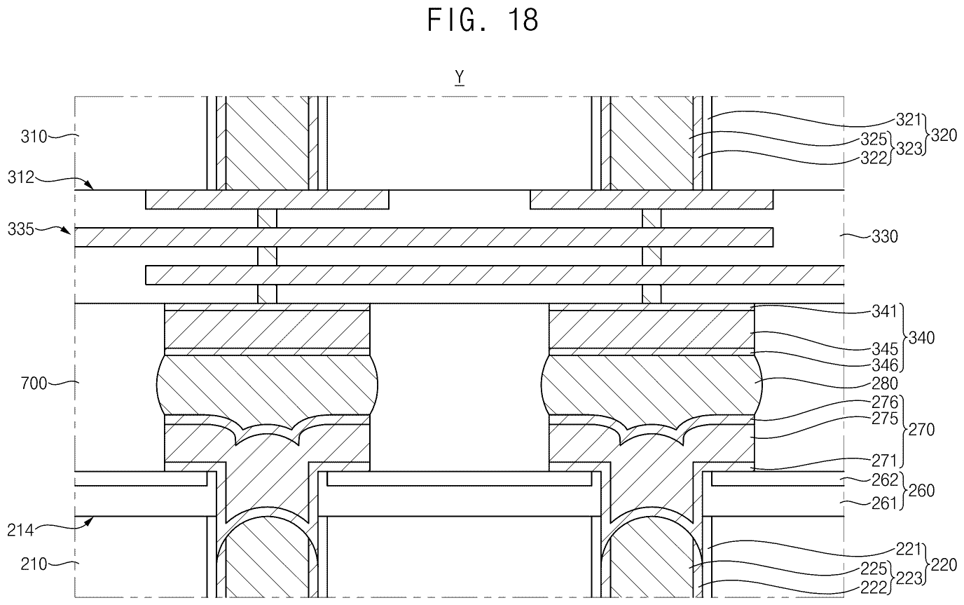

FIGS. 4 to 18 are cross-sectional views illustrating an example of a method of manufacturing a semiconductor package. FIG. 5 is an enlarged cross-sectional view of region Z of FIG. 4, FIGS. 7 to 10 are enlarged cross-sectional views of region Z of FIG. 6, FIGS. 12 and 14 are enlarged cross-sectional views of region W of FIGS. 11 and 13, respectively, FIG. 16 is an enlarged cross-sectional view of region X of FIG. 15, and FIG. 18 is an enlarged cross-sectional view of region Y of FIG. 17.

Referring to FIGS. 4 and 5, a first wafer W1 may be provided. In some implementations, the first wafer W1 may include a first substrate 110 having first and second surfaces 112 and 114 that are opposite to each other in the vertical direction. Additionally, the first wafer W1 may include a plurality of die regions DR and a scribe lane region SR at least partially surrounding each of the die regions DR. The first wafer W1 may be cut along the scribe lane region SR by a sawing process to be singulated into a plurality of first semiconductor chips.

In the die region DR, a circuit device may be formed on the first surface 112 of the first substrate 110. The circuit device may include circuit patterns, and a first insulating interlayer may be formed on the first surface 112 of the first substrate 110 to cover the circuit patterns.

A second insulating interlayer 130 may be formed on the first insulating interlayer, and a first wiring structure 135 may be disposed in the second insulating interlayer 130. A first conductive pad 140 may be formed on second insulating interlayer 130 to contact the first wiring structure 135 and to be electrically connected to the first wiring structure 135.

In some implementations, the first conductive pad 140 may be formed by the following processes.

A first seed layer may be formed on the second insulating interlayer 130, a first photoresist pattern including a first opening partially exposing an upper surface of the first seed layer may be formed on the first seed layer, and an electroplating process or an electroless plating process may be performed to form first and second conductive patterns 145 and 146 in the first opening.

The first photoresist pattern may be removed by, e.g., an ashing process and/or a stripping process to expose a portion of the first seed layer, the exposed portion of the first seed layer may be removed to form a first seed pattern 141 under the first conductive pattern 145.

Thus, a first conductive pad 140 including the first seed pattern 141 and the first and second conductive patterns 145 and 146 sequentially stacked in the vertical direction may be formed.

In some implementations, a first through electrode structure 120 extending in the vertical direction through an upper portion of the first substrate 110, e.g., a portion of the first substrate 110 adjacent to the first surface 112 thereof may be formed. In some implementations, the first through electrode structure 120 may include a third conductive pattern 125 extending in the vertical direction, a first barrier pattern 122 covering a sidewall and a lower surface of the third conductive pattern 125, and a first insulation pattern 121 covering a sidewall and a lower surface of the first barrier pattern 122. The third conductive pattern 125 and the first barrier pattern 122 may collectively form a first through electrode 123.

Referring to FIGS. 6 and 7, a first temporary adhesion layer 910 may be attached to a first carrier substrate C1, and the first temporary adhesion layer 910 may contact an upper surface of the second insulating interlayer 130 including the first wiring structure 135 and covering the first conductive pad 140 of the first wafer W1 so that the first carrier substrate C1 may be bonded to the first wafer W1.

The first temporary adhesion layer 910 may include a material that may lose adhesion by irradiating a light, e.g., ultraviolet (UV) light or heating. In some implementations, the first temporary adhesion layer 910 may include glue.

After flipping the first wafer W1, a portion of the first substrate 110 adjacent to the second surface 114 thereof may be removed by, e.g., a grinding process to expose an upper portion of the first through electrode structure 120.

In some implementations, an upper portion of the first insulation pattern 121 included in the first through electrode structure 120 may also be removed during the grinding process, and thus an upper outer sidewall of the first through electrode 123, that is, an upper outer sidewall of the first barrier pattern 122 may be exposed.

A first protective layer structure may be formed on the second surface 114 of the first substrate 110 to cover the first through electrode structure 120, and a planarization process may be performed on the first protective layer structure until an upper surface of the first through electrode 123 of the first through electrode structure 120 is exposed to form a first protective pattern structure 160.

In some implementations, the planarization process may include a chemical mechanical polishing (CMP) process and/or an etch back process.

In some implementations, the first protective layer structure may include first to third protective layers sequentially stacked in the vertical direction, and during the planarization process, the third protective layer may be removed and the second protective layer may partially remain. Thus, the first protective pattern structure 160 may include first and second protective patterns 161 and 162 sequentially stacked in the vertical direction. An upper outer sidewall of a portion of the first protective pattern 161 that is adjacent to the first through electrode structure 120 may be covered by the second protective pattern 162.

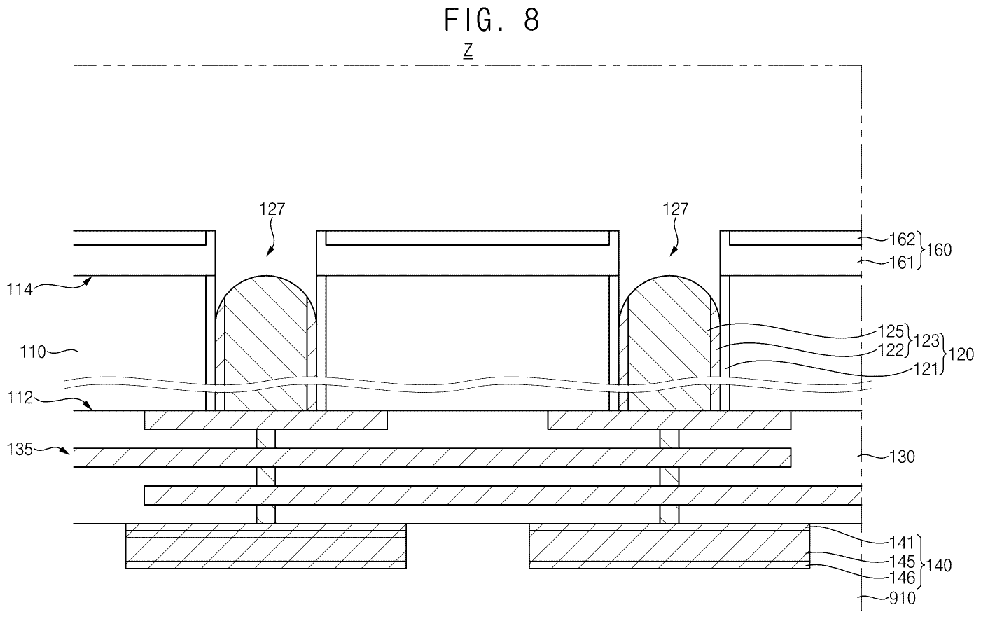

Referring to FIG. 8, an etching process may be performed on the first through electrode structure 120 to form a first recess 127.

In some implementations, the etching process may include a wet etching process, and an upper portion of the first through electrode 123 of the first through electrode structure 120 may be removed by the wet etching process.

In some implementations, the first through electrode 123 of the first through electrode structure 120 may have a convex upper surface after the etching process. In some implementations, an uppermost surface of the first through electrode 123 may be substantially coplanar with an upper surface of the first insulation pattern 121 and the second surface 114 of the first substrate 110.

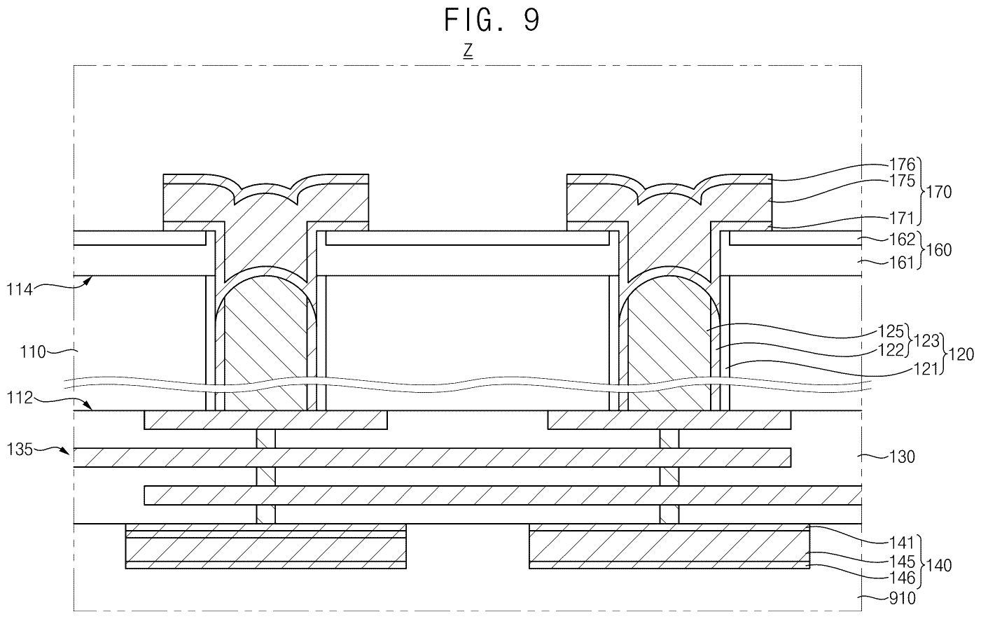

Referring to FIG. 9, a second conductive pad 170 may be formed on the first protective pattern structure 160 and the first through electrode structure 120 to fill the first recess 127.

In some implementations, the second conductive pad 170 may contact an upper surface of the first through electrode 123 of the first through electrode structure 120 to be electrically connected thereto.

In some implementations, the second conductive pad 170 may be formed by the following process.

A second seed layer may be formed on an upper surface of the first protective pattern structure 160, a sidewall of the first protective pattern structure 160 and an upper sidewall of the first insulation pattern 121 exposed by the first recess 127, and the upper surface of the first through electrode 123 exposed by the first recess 127, a second photoresist pattern having a second opening partially exposing an upper surface of the second seed layer may be formed on the second seed layer, and an electroplating process or an electroless plating process may be performed to form fourth and fifth conductive patterns 175 and 176 in the second opening.

The second photoresist pattern may be removed by, e.g., an ashing process and/or a stripping process to expose a portion of the second seed layer, and the exposed portion of the second seed layer may be removed to form a second seed pattern 171 under the fourth conductive pattern 175.

Thus, the second conductive pad 170 including the second seed pattern 171 and the fourth and fifth conductive patterns 175 and 176 sequentially stacked may be formed.

In some implementations, the second conductive pad 170 may include a lower portion disposed in the first recess 127 and contacting the upper surface of the first through electrode 123, and an upper portion contacting the lower portion and the upper surface of the first protective pattern structure 160 and having a planar area greater than that of the lower portion.

In some implementations, as the first through electrode 123 has the convex upper surface, a lower surface of the lower portion of the second conductive pad 170, which may contact the upper surface of the first through electrode 123, may be concave.

In some implementations, the second opening that may be formed in the second photoresist pattern for forming the second conductive pad 170 may be formed by a photo process and an etching process using the first recess 127 on the first through electrode 123 as a photo alignment key.

For example, the upper portion of the first through electrode 123 may be removed by the wet etching process to form the first recess 127, and thus a height difference between the upper surface of the first through electrode 123 under the first recess 127 and the upper surface of the first protective pattern structure 160 may occur. Using the height difference, a location of the second opening may be specified in the second photoresist pattern, and the specified portion of the second photoresist pattern may be removed by an exposure process and a development process to form the second opening.

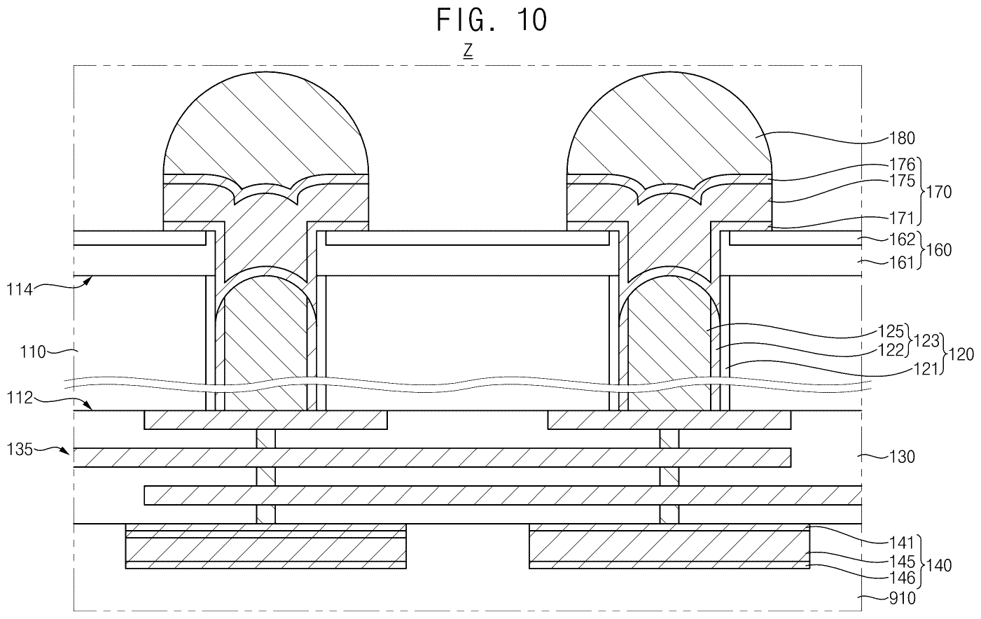

Referring to FIG. 10, a second conductive connection member 180 may be formed on the second conductive pad 170.

In some implementations, the second conductive connection member 180 may be formed by the following process.

A third photoresist pattern having a third opening exposing an upper surface of the second conductive pad 170 may be formed on the first protective pattern structure 160 and the second conductive pad 170, and electroplating process or an electroless plating process may be performed to form a preliminary second conductive connection member in the third opening. After removing the third photoresist pattern, a reflow process may be performed so that the preliminary second conductive connection member may be transformed into the second conductive connection member 180.

In some implementations, the second conductive connection member 180 may have a spherical shape or a hemispherical shape.

Referring to FIGS. 11 and 12, a second wafer W2 may be provided.

In some implementations, the second wafer W2 may include a second substrate 210 having first and second surfaces 212 and 214 that are opposite to each other in the vertical direction. The second wafer W2 may include a plurality of die regions DR and a scribe lane region SR at least partially surrounding each of the die regions DR. The second wafer W2 may be cut along the scribe lane region SR by a sawing process to be singulated into a plurality of second semiconductor chips.

In the die region DR, a circuit device may be formed on the first surface 212 of the second substrate 210. The circuit device may include circuit patterns, and a third insulating interlayer may be formed on the first surface 212 of the second substrate 210 to cover the circuit patterns.

A fourth insulating interlayer 230 may be formed on the third insulating interlayer, and may include a second wiring structure 235 therein. A third conductive pad 240 may be formed on the fourth insulating interlayer 230 to contact the second wiring structure 235 and to be electrically connected to the second wiring structure 235.

In some implementations, the third conductive pad 240 may be formed by processes substantially the same as or similar to those of the first conductive pad 140. Thus, a third conductive pad 240 including a third seed pattern 241 and fifth and sixth conductive patterns 245 and 246 sequentially stacked in the vertical direction may be formed.

In some implementations, a second through electrode structure 220 extending in the vertical direction through an upper portion of the second substrate 210, e.g., a portion of the second substrate 210 adjacent to the first surface 212 thereof may be formed. In some implementations, the second through electrode structure 220 may include an eighth conductive pattern 225 extending in the vertical direction, a second barrier pattern 222 covering a sidewall and a lower surface of the eighth conductive pattern 225, and a second insulation pattern 221 covering a sidewall and a lower surface of the second barrier pattern 222. The eighth conductive pattern 225 and the second barrier pattern 222 may collectively form a second through electrode 223.

Referring to FIGS. 13 and 14, processes substantially the same as or similar to those illustrated with respect to FIGS. 6 to 10 may be performed.

For example, a second temporary adhesion layer 920 may be attached to a second carrier substrate C2, and the second temporary adhesion layer 920 may contact an upper surface of the fourth insulating interlayer 230 including the second wiring structure 235 and covering the third conductive pad 240 of the second wafer W1 so that the second carrier substrate C2 may be bonded to the second wafer W2.

The second temporary adhesion layer 920 may include a material that may lose adhesion by irradiating a light, e.g., UV light or heating. In some implementations, the second temporary adhesion layer 920 may include glue.

After flipping the second wafer W2, a portion of the second substrate 210 adjacent to the second surface 214 thereof may be removed by, e.g., a grinding process to expose an upper portion of the second through electrode structure 220, a first protective layer structure may be formed on the second surface 214 of the second substrate 210 to cover the second through electrode structure 220, and a planarization process may be performed on the second protective layer structure until an upper surface of the second through electrode 223 of the second through electrode structure 220 is exposed to form a second protective pattern structure 260. The second protective pattern structure 160 may include third and fourth protective patterns 261 and 262 sequentially stacked in the vertical direction.

An etching process, e.g., a wet etching process may be performed on the second through electrode structure 220 so that an upper portion of the second through electrode 223 of the second through electrode structure 220 may be removed to form a second recess, and a fourth conductive pad 270 may be formed on the second protective pattern structure 260 and the second through electrode structure 220 to fill the second recess. The fourth conductive pad 270 may include a fourth seed pattern 271 and ninth and tenth conductive patterns 275 and 276 sequentially stacked may be formed.

In some implementations, the fourth conductive pad 270 may include a lower portion disposed in the second recess and contacting the upper surface of the second through electrode 223, and an upper portion contacting the lower portion and the upper surface of the second protective pattern structure 260 and having a planar area greater than that of the lower portion.

A third conductive connection member 280 may be formed on the fourth conductive pad 270.

Referring to FIGS. 15 and 16, the second wafer W2 may be flipped, and may be attached to an upper surface of a third temporary adhesion layer on a ring frame.

The third temporary adhesion layer may cover the fourth conductive pad 270 and the third conductive connection member 280 on the second surface 214 of the second wafer W2.

The second temporary adhesion layer 920 attached to the second carrier substrate C2 may be separated from the third conductive pad 240 and the fourth insulating interlayer 230 so that the second carrier substrate C2 may be separated from the second wafer W2.

The second wafer W2 may be cut along the scribe lane region SR by, e.g., a sawing process to be singulated into a plurality of second semiconductor chips 200, and a bonding layer 700 may be attached to the fourth insulating interlayer 230 of each of the second semiconductor chips 200. The bonding layer 700 may cover the third conductive pad 240 on the fourth insulating interlayer 230.

In some implementations, the bonding layer 700 may be attached to the fourth insulating interlayer 230 of the second wafer W2 before the sawing process.

Each of the second semiconductor chips 200 may be mounted on the first wafer W1 such that the bonding layer 700 may cover the second conductive pad 170 and the second conductive connection member 180 of the first wafer W1. The second semiconductor chips 200 may be arranged on the die regions DRs, respectively, of the first wafer W1, and the third conductive pad 240 of the second semiconductor chip 200 may contact an upper surface of the second conductive connection member 180 of a corresponding one of the first semiconductor chip.

A thermal compression bonding (TCB) process may be performed at a temperature of equal to or less than about 400° C., so that the second semiconductor chips 200 may be bonded to the first wafer W1.

During the TCB process, a NCF included in the bonding layer 700 may be melted to have fluidity, and may flow in a space between the second semiconductor chips 200 and the first wafer W1. The NCF may be cured to fill the space.

Referring to FIGS. 17 and 18, third to fifth semiconductor chips 300, 400 and 500 may be sequentially stacked on the second semiconductor chip 200.

That is, processes substantially the same as or similar to those illustrated with respect to FIGS. 11 to 16 may be performed to form a plurality of third semiconductor chips 300, and each of the third semiconductor chips 300 may be stacked on the second semiconductor chip 200.

In some implementations, the third semiconductor chip 300 may include a third substrate 310 having first and second surfaces 312 and 314 that are opposite to each other in the vertical direction, and may be stacked on the second semiconductor chip 200 such that the bonding layer 700 covering a sixth insulating interlayer 330, which is disposed on the first surface 312 of the third substrate 310, may contact the fourth conductive pad 270 and the third conductive connection member 280, which is disposed on the second surface 214 of the second substrate 210. A fifth conductive pad 340 of the third semiconductor chip 300 may be bonded to the third conductive connection member 280 of a corresponding one of the second semiconductor chips 200.

Likewise, a fourth semiconductor chip 400 including a fourth substrate 410 having first and second surfaces 412 and 414 that are opposite to each other in the vertical direction may be stacked on the third semiconductor chip 300, and a seventh conductive pad 440 of the fourth semiconductor chip 400 may be bonded to a fourth conductive connection member 380 of the third semiconductor chip 300. Additionally, a fifth semiconductor chip 500 including a fifth substrate 510 having first and second surfaces 512 and 514 that are opposite to each other in the vertical direction may be stacked on the fourth semiconductor chip 400, and a ninth conductive pad 540 of the fifth semiconductor chip 500 may be bonded to a fifth conductive connection member 480 of the fourth semiconductor chip 400.

Referring to FIGS. 1 to 3 again, a molding member 600 may be formed on the first wafer W1 to fill a space between structures each of which may include the second to fifth semiconductor chips 200, 300, 400 and 500.

In some implementations, the molding member 600 may expose an upper surface of the fifth semiconductor chip 500.

The first wafer W1 may be cut along the scribe lane region SR by, e.g., a sawing process to be singulated into a plurality of first semiconductor chips 100.

During the sawing process, the molding member 600 may also be cut to cover sidewalls of the second to fifth semiconductor chips 200, 300, 400 and 500 on each of the first semiconductor chips 100.

After flipping the first semiconductor chip 100, the first temporary adhesion layer 910 and the first carrier substrate C1 may be separated from each of the first semiconductor chips 100 to expose the first conductive pad 140, a first conductive connection member 150 may be formed on an upper surface of the first conductive pad 140, and the first semiconductor chip 100 may be flipped again so as to complete the manufacturing of the semiconductor package.

As illustrated above, the upper portions of the first to third through electrodes 123, 223 and 323 and the fourth through electrode that are disposed in the first to fourth semiconductor chips 100, 200, 300 and 400, respectively, may be partially removed to form the first recess 127, the second recess, the third recess and the fourth recess, respectively, and the second, fourth, sixth and eighth conductive pads 170, 270, 370 and 470 may be formed using the first recess 127, the second recess, the third recess and the fourth recess, respectively. For example, the recesses can be used effectively as photo alignment keys.

If the first recess and the second to fourth recesses are not formed on the first to third through electrodes 123, 223 and 333 and the fourth through electrode, respectively, photo alignment keys may be formed on the first to fourth protective pattern structures 160, 260, 360 and 460, respectively, and thus photo processes and etching processes for forming the photo alignment keys have to be performed, complicating fabrication and introducing additional time, cost, opportunity for defects, and the like.

However, in some implementations, only the etching process (e.g., wet etching process) may be performed on the first to third through electrodes 123, 223 and 323 and the fourth through electrode to form the first recess 127 and the second to fourth recesses, respectively, without performing photo processes, and the first recess 127 and the second to fourth recesses may be used as photo alignment keys, so that the number of processes for manufacturing the semiconductor package may be reduced.

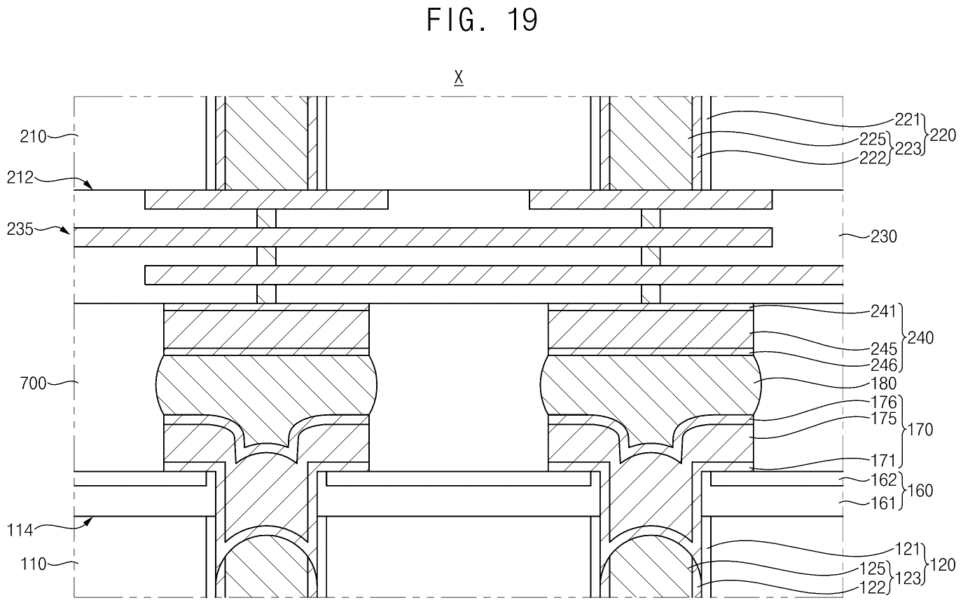

FIGS. 19 to 21 are cross-sectional views illustrating examples of semiconductor packages, which may correspond to FIG. 2. Each of these semiconductor packages may be substantially the same as or similar to that of FIGS. 1 to 3, except for the shapes of the through electrode structure and the conductive pad, and thus repeated explanations are omitted herein. The description provided for FIGS. 1 to 3 can be applied similarly to FIGS. 19 to 21, except where noted otherwise or suggested otherwise by context.

Referring to FIG. 19, the uppermost surface of the first through electrode 123 may be lower than the upper surface of the first insulation pattern 121 and the second surface 114 of the first substrate 110.

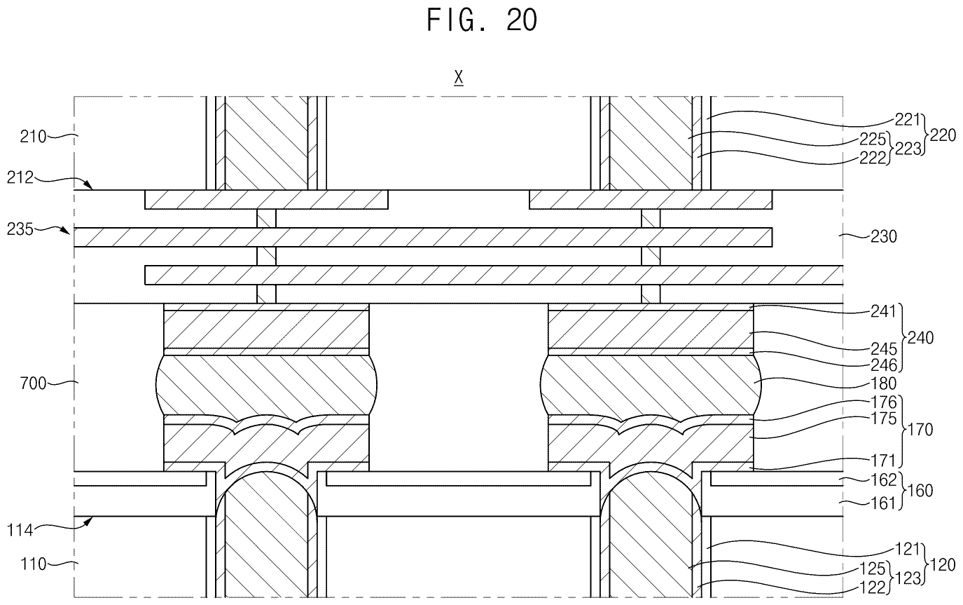

Referring to FIG. 20, the uppermost surface of the first through electrode 123 may be substantially coplanar with the upper surface of the first protective pattern structure 160.

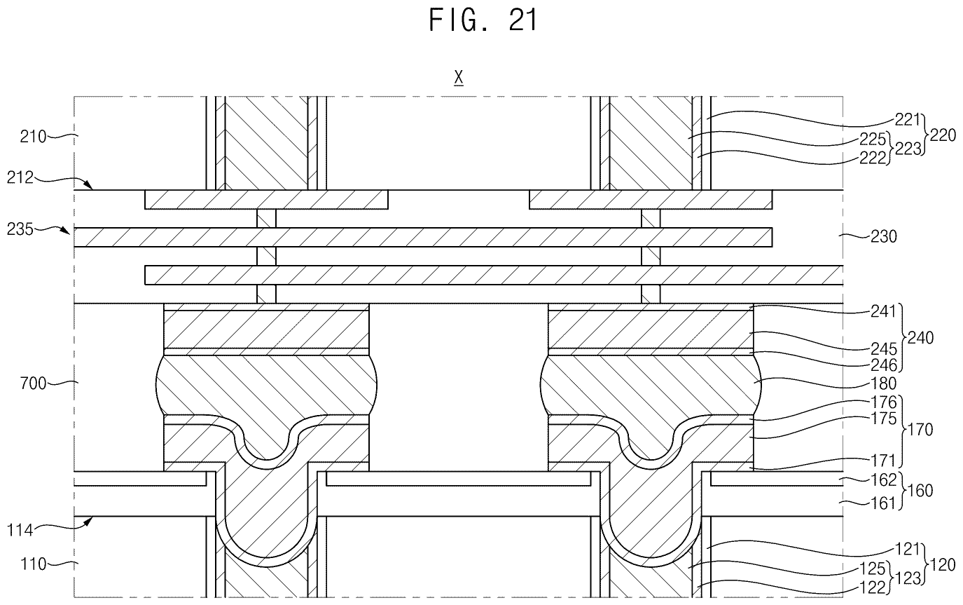

Referring to FIG. 21, the upper surface of the first through electrode 123 may be concave. Thus, the lower portion of the second conductive pad 170 on the first through electrode 123 may have a convex lower surface, and the upper surface of the central portion of the second conductive pad 170 may be concave.

The first through electrode structure 120 and the second conductive pad 170 are illustrated with reference to FIGS. 19 to 21, however, this description may also be applied to the second to fourth through electrode structures 220, 320 and 420 and the fourth, sixth and eighth conductive pads 270, 370 and 470.

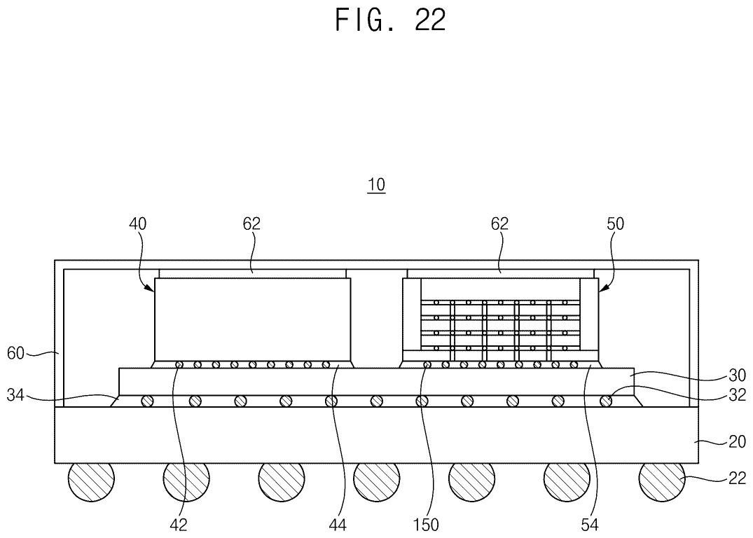

FIG. 22 is a cross-sectional view illustrating an example of an electronic device.

This electronic device may include a semiconductor package as shown in FIGS. 1 to 3 or FIGS. 19 to 21 as a second semiconductor device 50.

Referring to FIG. 22, an electronic device 10 may include a package substrate 20, an interposer 30, a first semiconductor device 40 and the second semiconductor device 50. The electronic device 10 may further include first, second and third underfill members 34, 44 and 54, a heat slug 60, and a heat dissipation member 62.

In some implementations, the electronic device 10 may be a memory module having a 2.5D package structure, and thus, may include the interposer 30 for electrically connecting the first and second semiconductor devices 40 and 50 to each other.

In some implementations, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may include a semiconductor package, e.g., an HBM package.

In some implementations, the package substrate 20 may have an upper surface and a lower surface that are opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a seventh conductive connection member 32. In some implementations, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 and/or electrically connected to the package substrate 20 through the seventh conductive connection member 32. The seventh conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through an eighth conductive connection member 42. For example, the eighth conductive connection member 42 may include, e.g., a micro-bump.

In addition, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by, e.g., a flip chip bonding process. In this case, conductive pads of the second semiconductor device 50 may be electrically connected to conductive pads of the interposer 30 by the first conductive connection member 150.

Although a single first semiconductor device 40 and a single second semiconductor device 50 are illustrated as being disposed on the interposer 30, the number of semiconductor devices is not limited thereto, and a plurality of first semiconductor devices 40 and/or a plurality of second semiconductor devices 50 may be disposed on the interposer 30.

In some implementations, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive including an epoxy material.

The semiconductor device 50 may include a buffer die and a plurality of memory dies sequentially stacked on the buffer die. The buffer die and the memory dies may be electrically connected to each other by through electrodes, e.g., TSVs, and the through electrodes may be electrically connected to each other by conductive connection members. Data signals and control signals may be transferred to the buffer die and the memory dies by the through electrodes.

In some implementations, the heat slug 60 be formed on the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a sixth conductive connection member 22 may be disposed beneath the conductive pad. In some implementations, a plurality of sixth conductive connection members 22 may be spaced apart from each other in the horizontal direction. The sixth conductive connection member 22 may be, e.g., a solder ball. The electronic device 10 may be mounted on a module board via the sixth conductive connection members 22 to form a memory module.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of various examples. Although these examples have been described, those skilled in the art will readily appreciate that many modifications are possible without materially departing from the scope of the present disclosure.

What is claimed is:

1. A semiconductor package comprising:
a substrate having first and second surfaces opposite to each other in a vertical direction;
a through electrode extending in the substrate and having an upper surface that includes a curved portion;
a protective pattern structure on the second surface of the substrate; and
a conductive pad extending in the protective pattern structure,
wherein the conductive pad is in contact with an upper surface of the protective pattern structure, and
wherein the conductive pad is in contact with the upper surface of the through electrode.

2. The semiconductor package of claim 1, wherein an uppermost surface of the through electrode is coplanar with the second surface of the substrate.

3. The semiconductor package of claim 2, wherein a lower portion of the conductive pad at least partially overlaps an upper portion of the through electrode and an upper portion of the substrate along a horizontal direction.

4. The semiconductor package of claim 1, wherein an uppermost surface of the through electrode is lower than the second surface of the substrate.

5. The semiconductor package of claim 1, wherein an uppermost surface of the through electrode is higher than the second surface of the substrate and lower than the upper surface of the protective pattern structure.

6. The semiconductor package of claim 1, wherein an uppermost surface of the through electrode is coplanar with the upper surface of the protective pattern structure.

7. The semiconductor package of claim 1, wherein a planar area of an upper portion of the conductive pad is greater than a planar area of a lower portion of the conductive pad.

8. The semiconductor package of claim 1, wherein an upper surface of the conductive pad includes a first central portion and a second central portion in a plan view, and
wherein the first central portion is convex, and the second central portion surrounds the first central portion and is concave.

9. The semiconductor package of claim 8, further comprising a conductive bump contacting an upper surface of the conductive pad,
wherein a lower surface of the conductive bump has a shape corresponding to a shape of the upper surface of the conductive pad.

10. The semiconductor package of claim 1, wherein a central portion of the conductive pad has a concave upper surface.

11. The semiconductor package of claim 1, further comprising an insulation pattern extending in the substrate and covering a sidewall of the through electrode.

12. A semiconductor package comprising:
a substrate having first and second surfaces opposite to each other in a vertical direction;
a through electrode extending in the substrate;
a protective pattern structure on the second surface of the substrate; and
a conductive pad including:
a seed pattern on an upper surface and a sidewall of the protective pattern structure, and on an upper surface of the through electrode; and
a first conductive pattern on the seed pattern,
wherein the first conductive pattern at least partially overlaps the sidewall of the protective pattern structure along a horizontal direction, and
wherein the first conductive pattern at least partially overlaps the upper surface of the protective pattern structure along the vertical direction,
wherein each of a lower surface and an upper surface of the conductive pad is at least partially curved.

13. The semiconductor package of claim 12, wherein the conductive pad includes a second conductive pattern on the first conductive pattern, the second conductive pattern including a material different from a material of the first conductive pattern.

14. The semiconductor package of claim 12, wherein the lower surface of the conductive pad is in contact with the upper surface of the through electrode and includes a concave portion.

15. The semiconductor package of claim 12, wherein the lower surface of the conductive pad is in contact with the upper surface of the through electrode and includes a convex portion.

16. The semiconductor package of claim 12, wherein an upper surface of the conductive pad includes a first central portion and a second central portion in a plan view, and
wherein the first central portion is convex, and the second central portion surrounds the first central portion and is concave.

17. A semiconductor package comprising:
a first semiconductor chip including:
a first substrate having first and second surfaces opposite to each other in a vertical direction;
a first through electrode extending in the first substrate and having an upper surface that includes a curved portion;
a first protective pattern structure on the second surface of the first substrate; and
a first conductive pad extending in the first protective pattern structure;
a conductive bump on the first conductive pad; and
a second semiconductor chip including:
a second substrate having first and second surfaces opposite to each other in the vertical direction;
a second through electrode extending in the second substrate; and
a second conductive pad on the first surface of the second substrate and in contact with an upper surface of the conductive bump,
wherein the first conductive pad is in contact with an upper surface of the first protective pattern structure, and
wherein the first conductive pad is in contact with the upper surface of the first through electrode.

18. The semiconductor package of claim 17, wherein the second semiconductor chip includes:
a second protective pattern structure on the second surface of the second substrate; and
a third conductive pad including:
a lower portion extending in the second protective pattern structure and in contact with an upper surface of the second through electrode, and
an upper portion on the lower portion and in contact with an upper surface of the second protective pattern structure.

19. The semiconductor package of claim 17, further comprising a bonding layer between the first and second semiconductor chips, the bonding layer covering the first and second conductive pads and the conductive bump.

20. The semiconductor package of claim 17, wherein the first semiconductor chip is a buffer die, and the second semiconductor chip is a memory die.
